(19) United States
(12) Patent Application Publication
(10) Pub. No.: US 2021/0105000 A1
(43) Pub. Date: Apr. 8, 2021

(54) PEDESTAL MOUNTED WITH BLANK, CRYSTAL UNIT AND OSCILLATOR

(71) Applicant: NIHON DEMPA KOGYO CO., LTD., Tokyo (JP)

(72) Inventor: Takafumi SAITOH, Saitama (JP)

(73) Assignee: NIHON DEMPA KOGYO CO., LTD., Tokyo (JP)

(21) Appl. No.: 17/020,835

(22) Filed: Sep. 15, 2020

(30) Foreign Application Priority Data
Oct. 4, 2019 (JP) 2019-183886

(51) Int. Cl. H03H 9/05

(52) U.S. Cl. CPC H03H 9/0547

(57) ABSTRACT

A substantially rectangular pedestal for mounting a blank is provided, wherein angled portions at four corners of the main body of the pedestal is formed in a shape that is cut out obliquely.

### CROSS-REFERENCE TO RELATED APPLICATIONS

This application claims the priority benefit of Japanese Patent Application No. 2019-183886, filed on Oct. 4, 2019. The entirety of the above-mentioned patent application is hereby incorporated by reference herein and made a part of this specification.

### BACKGROUND

### Technical Field

The disclosure relates to a pedestal mounted with a blank (vibrating element), a crystal unit, and an oscillator and in particular, to a pedestal, a crystal unit, and an oscillator capable of sufficiently securing an area of a blank and an electrode and improving vibration characteristics without being in contact with an inner wall of a recess of a package having rounded corners of the recess.

### Description of Related Art

In the conventional crystal unit, a structure using a pedestal (crystal pedestal) mainly composed of crystals is known as a structure to suppress the impact on the crystal piece from the package and the outside of the package and to improve phase noise characteristics. Further, in the package having a recess, there is an oscillator mounted with the crystal piece and an IC (Integrated Circuit) of an oscillator circuit.

Further, the package has an H-type structure in which recesses are formed on the front and back, and a crystal piece and a crystal pedestal are mounted on the front side, and there is a crystal oscillator in which an IC of an oscillation circuit is mounted on the back side. There is a temperature-compensated crystal oscillator (TCXO: Temperature Compensated Crystal Oscillator) in which a temperature-compensating circuit is provided on the front or back surface of the package.

[Shape of the Package Recess]

In the case of a crystal unit equipped with a blank on top of the pedestal, from the point of view of reliability, the shape of the recess of the package on which the pedestal is mounted is rounded corners so that stress is not concentrated (R-chamfered). In order to improve the CI (Crystal Impedance) characteristics of the crystal unit, it is desirable to design the outer shapes of the blanks and the electrodes to be large (wide). Therefore, without being in contact with the R-chamfered side surface of the recess of the package, it is necessary to secure the pedestal with a large area as much as possible.

[Beveling]

Further, some crystal blanks are beveled, in which the central portion is thicker and the peripheral portion is thinner, and the outer peripheral portion is polished to chamfer, in order to improve the vibration characteristics.

[Form of Conventional Pedestal: FIG. 6]

Here, the shape of a conventional pedestal will be described using FIG. 6. FIG. 6 is a plan view illustrating the shape of the conventional pedestal. FIG. 6 shows a state in which the pedestal 4 on which the blank 5 is mounted is fixed on a substrate in a recess 11 of the package 1 made of ceramic or the like. As shown in FIG. 6, the conventional pedestal 4 is formed in a rectangular shape with crystals or the like, and the angled portions are formed at substantially right angles.

As described above, the angled portion 12 of the recess is rounded, and the inner wall of the package 1 projects more inward than when the angled portion 12 are formed at right angles. Therefore, the conventional pedestal 4 is formed in a dimension that is not in contact with the angled portion 12 of the recess 11, the blank 5 has been formed in a shape to be mounted on the pedestal 4. When the pedestal 4 or the blank 5 contacts the package, the vibration characteristics of the blank 5 deteriorate. FIG. 6 shows L1′>L2′>L3′ where L1′ is the dimension of the long side of the recess 11, L2′ is the dimension of the long side of the pedestal 4, and L3′ is the long side of the blank.

As shown in FIG. 6, as compared with the length L1′ of the long side of the recess 11, the length L2′ of the long side of the pedestal 4 is formed sufficiently small, a wide gap is formed between the inner wall of the recess 11 of the package 1 and the pedestal 4. In other words, the pedestal 4 and the blank 5 have a small shape in view of the size of the package 1, so that it was impossible to mount a pedestal or blank with a sufficient size to effectively utilize the area of the recess 11.

In addition, as the related art of the crystal unit with a pedestal, there is “Crystal Oscillator” of Japanese Patent No. 3017750. Japanese Patent No. 3017750 discloses a crystal unit in which a crystal holding blank having a recess is fixed on a base, and a rectangular crystal element is mounted on the recess. Japanese Patent No. 3017750 also discloses that a fixing direction connecting the both end portions to be fixed of the crystal holding blank and the fixing direction connecting the both end portions in the longitudinal direction to be fixed of the crystal element are orthogonal.

However, in the crystal unit using the conventional pedestal, since the angled portions of the recess of the package are rounded, the size of the pedestal must be limited so as not to contact the inner wall protruding inward. The gap will occur around the pedestal, and there is a problem that it is not easy to sufficiently widen the area of the blank and the electrode to effectively utilize the area of the recess.

In addition, Japanese Patent No. 3017750 does not disclose the angled portions of the pedestal for suppressing vibration from the outside (vibration damping pedestal) are cut out obliquely.

As described above, the disclosure provides a pedestal, a crystal unit, and an oscillator capable of obtaining good vibration characteristics to sufficiently secure the area of the blank and the electrode when the angled portion of the recess is mounted in a rounded package,

### SUMMARY

According to one embodiment of this disclosure, there is provided a substantially rectangular pedestal for mounting a blank, wherein angled portions at four corners of a pedestal body is formed in a shape that is cut out obliquely.

### BRIEF DESCRIPTION OF THE DRAWINGS

The foregoing and additional features and characteristics of this disclosure will become more apparent from the following detailed description considered with reference to the accompanying drawings.

FIG. 1 is a view for illustrating the shape of the first pedestal.

FIG. 2 is a top view for illustrating a configuration of a crystal unit using the first pedestal.

FIG. 3 is view for illustrating the shape of the second pedestal.

FIG. 4 is a cross-sectional view for explanation of a crystal unit using the second pedestal.

FIG. 5 is a sectional view for explanation of a configuration of an oscillator using the second pedestal.

FIG. 6 is a plan view illustrating the shape of a conventional pedestal.

### DETAILED DESCRIPTION

Embodiments of the disclosure will be described with reference to the drawings.

### Outline of Embodiment

The pedestal (this pedestal) according to the embodiment of the disclosure is a pedestal which is substantially rectangular and on which a blank is mounted, and angled portions of four corners of the pedestal are formed in a shape that is obliquely cut (C-chamfered). Even if the angled portions of a recess in the package are formed to be rounded (R-chamfered), the angled portions are not in contact with the inner wall of the recess. By increasing the dimensions of the long sides and short sides of the pedestal, it is possible to sufficiently secure the area of the blank and the electrode to obtain good vibration characteristics.

Furthermore, the present pedestal is substantially rectangular and in which a recess is formed in a central portion of a surface on which a blank is mounted and an edge portion is formed adjacent to the recess, the angled portions at the four corners are C-chamfered. Even if the angled portions of the recess in the package are formed to be rounded, the angled portions are not in contact with the inner wall of the recess. The dimensions of the long sides and the short sides of the pedestal can be increased, and the beveled blank central portion can be prevented from being in contact with the pedestal surface, thereby improving the vibration characteristics.

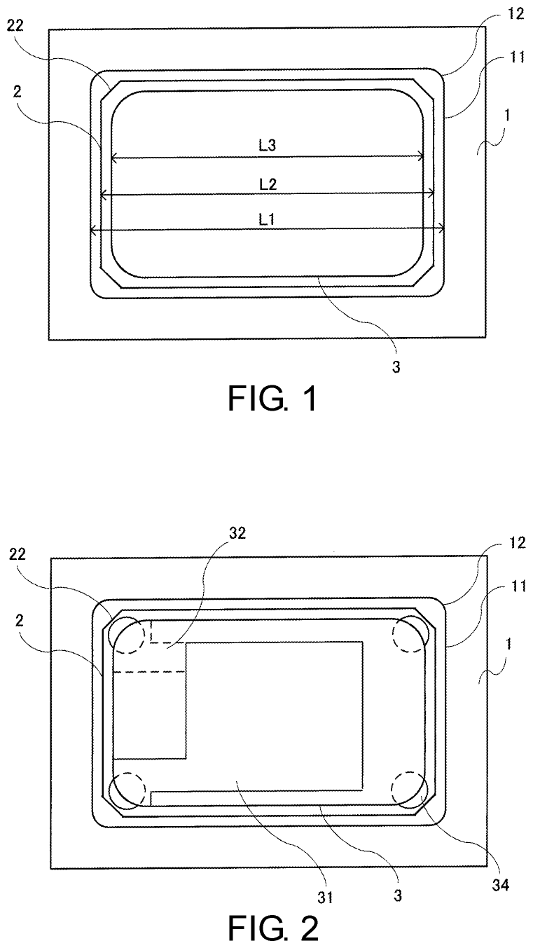

Further, the crystal unit according to the embodiment of the disclosure (the present crystal unit) is a surface-mounted type crystal unit which is housed in a package by mounting a blank on the pedestal, the oscillator according to the embodiment of the disclosure (the present oscillator) is provided with an oscillation circuit in the same package as the present crystal unit.

[The Shape of the First Pedestal: FIG. 1]

The shape of the pedestal (first pedestal) according to the first embodiment of the disclosure will be described with reference to FIG. 1. FIG. 1 is an explanatory drawing illustrating a shape of the first pedestal. In FIG. 1, in the recess of the package 1, the first pedestal 2 is mounted, and a state of mounting the blank 3 on the first pedestal 2 viewing from above is further shown. As shown in FIG. 1, the angled portions 12 of the recess 11 of the package 1 is R-chamfered (inner diameter R) to form round. Further, here, the blank 3 is chamfered (beveled) so that the periphery is thin and the center is thick and the angled portions are rounded, but blank 3 may be shaped without beveling.

The first pedestal 2 is formed of crystals or the like, has a substantially rectangular shape, and is formed in a shape in which the angled portions 22 at the four corners are obliquely cut out. That is, in the first pedestal 2, the angled portions 22 at the four corners are C-chamfered.

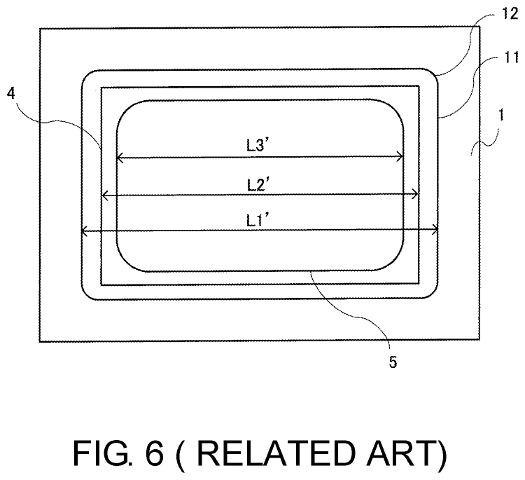

As a result, the first pedestal 2 can increase the area of the pedestal to effectively utilize the area of the recess without being in contact with the inner surface of the package 1. Specifically, the first pedestal 2 is formed larger as compared with the conventional pedestal 4 shown in FIG. 6. It can be seen the gap between the long and short sides of the first pedestal 2 and the side surface of the recess 11 of the package 1 is narrowed.

The relationship among the length L1 of the long side of the recess 11 of the package 1, the length L2 of the long side of the first pedestal 2, and the length L3 of the long side of the blank 3 is L1>L2≥L3. Further, although not shown for the short side, the relationship is the same as for the long side, and the length of the short side of the recess 11>the length of the short side of the first pedestal≥the length of the short side of the blank 3. That is, the first pedestal 2 and the blank 3 may have the same size. However, when the blank 3 is the same size as the first pedestal 2, the blank 3 is assumed to be chamfered so as not to protrude from the angled portion of the pedestal 2 which is C-chamfered.

[Configuration of the Crystal Unit Using the First Pedestal: FIG. 2]

Next, the configuration of the crystal unit using the first pedestal will be described with reference to FIG. 2. FIG. 2 is a top view illustrating a configuration of a crystal unit using the first pedestal (the first crystal unit). As shown in FIG. 2, the first crystal unit has a configuration in which a blank 3 is mounted on the first pedestal 2 shown in FIG. 1, and four corners are fixed by a conductive adhesive 34. An excitation electrode 31 is formed on the front surface of the blank 3, and an excitation electrode 32 is formed on the back surface of the blank 3, and the excitation electrodes 31 and 32 are connected to electrodes and wirings formed on the front surface of the first pedestal by the conductive adhesive 34.

Since the angled portion 22 is C-chamfered, even if the long side and the short side are longer than the conventional one, the first pedestal 2 is not in contact with the angled portion 12 of the recess 11 of the package 1. The area of the pedestal surface is larger than the conventional one and the area of the blank 3 mounted on the pedestal and the area of the electrode and the wiring (not shown) formed on the pedestal surface can be increased, and thus, good characteristics can be obtained.

[Oscillator Using the First Pedestal]

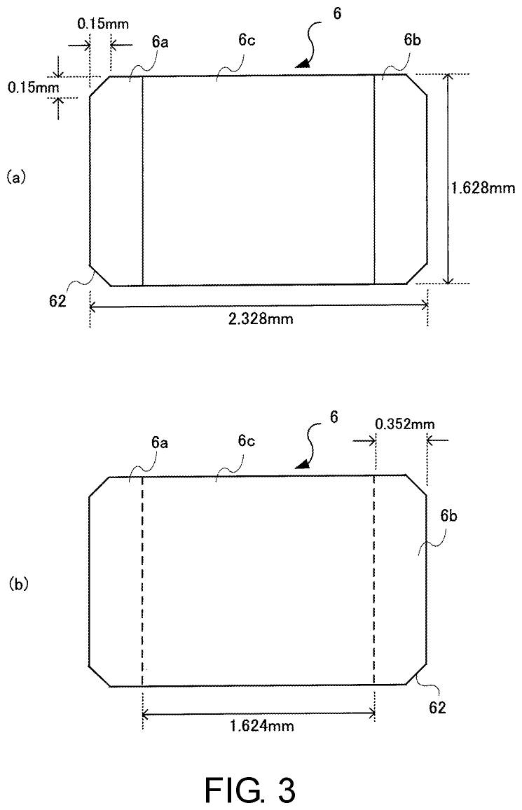

Although not shown, for example, for an H-shaped package with recesses on the front and back surfaces, an oscillator is constructed by mounting the first pedestal 2 with the blank 3 mounted in one of the recesses, and mounting an oscillator circuit in the other recess, and connecting the blank 3 to the oscillator circuit.

[The Shape of the Second Pedestal: FIG. 3]

Next, the shape of the pedestal (the second pedestal) according to the second embodiment of the disclosure will be described with reference to FIG. 3. FIG. 3 is an explanatory view illustrating the shape of the second pedestal, in which (a) is a top view and (b) is a bottom view. The second pedestal 6 is a pedestal for mounting a beveled blank, as shown in FIG. 3 (a), and a recess 6c is formed in the surface central portion. The recess 6c is formed from one long side of the main body of the second pedestal 6 to the other long side. Between the short side of the main body of the pedestal 6 and the recess 6c, edge portions 6a and 6b are provided as edges.

The recess 6c, by photolithography and wet etching, is formed by scraping the surface of the second pedestal 6. Specifically, staring with a flat surface state of the main body of the pedestal 6, the recess 6c is formed by scraping the main body with wet etching by masking the edge portions 6a and 6b by photolithography.

The beveled blank has a convex shape in the center as compared with the peripheral portion. As a result, the central portion of the blank may be in contact with the surface of the pedestal 6 when the blank is fixed on the pedestal 6 by the conductive adhesive 34. In the second pedestal 6, since the recess 6c is provided, the blank can be prevented from being in contact with the pedestal 6 by positioning the central portion of the blank above the recess 6c when the beveled blank is mounted.

Then, in the second pedestal 6, the corner portion 62 is C-chamfered into a shape that is cut out obliquely. The second pedestal 6 has a substantially rectangular shape with a long side of 2.328 mm and a short side of 1.628 mm, and the angled portion 62 is cut out obliquely by 0.15 mm on each of the long side and the short side. The recess 6c has a length of 1.624 mm and a depth of 0.035 mm along the long side of the main body of the second pedestal 6. The edge portions 6a and 6b are formed to have a width of 0.352 mm.

Thus, in the second pedestal 6, the pedestal having the recess for mounting the beveled blank, even when mounting in a package of which corners of the recess are formed to be rounded, it does not contact the angled portions of the recess. The area can be increased by lengthening the long and short sides of the pedestal 6, the area of the electrodes formed on the pedestal 6 and the blank to be mounted is increased and thus the characteristics can be improved.

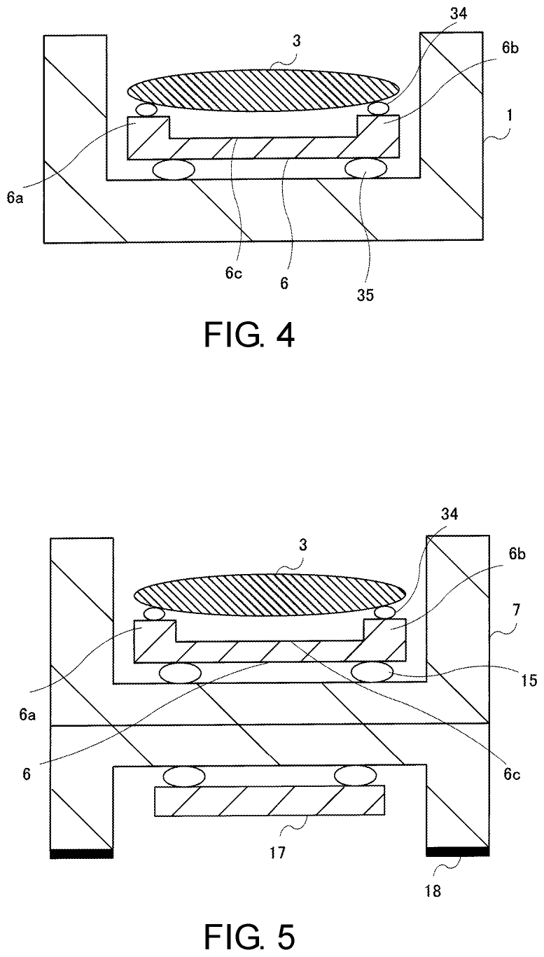

Further, here, although the shape of the recess 6c is formed from one long side of the main body of the pedestal 6 over the other long side, the shape may be entirely surrounded by edge portions without being in contact with any side of the main body of the pedestal 6.

[Cross-Sectional View for Illustration of the Crystal Unit Using the Second Pedestal: FIG. 4]

Next, the configuration of the crystal unit using the second pedestal 6 will be described with reference to FIG. 4. FIG. 4 is a cross-sectional view for explanation of the crystal unit using the second pedestal (the second crystal unit). As shown in FIG. 4, the second crystal unit has a configuration in which the second pedestal 6 mounted with a beveled blank 3 is fixed to a recess of a package 1 made of a ceramic or the like similar to the conventional one by a solder (or conductive adhesive) 35. Then, the blank 3 is fixed by the conductive adhesive 34 on the edge portions 6a and 6b of the second pedestal 6.

As described above, since the central portion of the blank 3 is mounted on the recess 6c of the second pedestal 6, even if the central portion of the blank 3 is convex downward, the convex portion can be absorbed by the depth of the recess 6c and the blank 3 can be held in a manner that the central portion of the blank 3 is not in contact with the inner back surface of the recess 6, so as not to interfere with the vibration.

[Cross-Sectional Illustration of an Oscillator Using the Second Pedestal: FIG. 5]

Next, the configuration of the oscillator using the second pedestal 6 will be described with reference to FIG. 5. FIG. 5 is a cross-sectional view for explanation of a configuration of an oscillator using the second pedestal (the second oscillator). As shown in FIG. 5, in the second oscillator, an H-shaped package 7 is provided to have recesses on the front surface and the back surface, the second pedestal 6 and the beveled blank 3, similar to the second crystal unit described above, are mounted on the recess of the front surface of the H-shaped package 7, and an oscillation circuit 17 is mounted on the recess of the back surface of the H-shaped package 7.

Electrodes and wirings are formed on the recess surface of the front surface of the package 7 and the recess surface of the back surface of the package 7, the electrode on the recess of the front surface and the electrode one the recess of the back surface are connected by a through hole or the like formed in the package 7. Then, the excitation electrodes 31 and 32 of the blank 3 and the oscillation circuit 17, and external terminals 18 provided on the back surface of the package 7 are electrically connected. In the second oscillator, the blank 3 is not in contact with the second pedestal 6, so that good characteristics are obtained without interfering with the vibration.

Further, instead of an H-shaped package, it may be configured that the second pedestal with the blank 3 and the oscillator circuit are arranged side by side in a package provided with only one recess.

### Effects of Embodiment

According to the first pedestal 2, the pedestal 2 is substantially rectangular and on which the blank 3 is mounted, and the angled portions 22 of the four corners of the main body of the pedestal 2 is C-chamfered and formed in a shape that is cut out obliquely. Therefore, even if the angled portions 12 of the inner wall of the recess 11 are formed to be rounded by R-chamfering on the angled portions 12 of the inner wall of the recess 11, the long and short sides of the pedestal 2 can be lengthened without being in contact with the angled portions 12 of the recess 11, and the area of the electrodes and wirings formed on the surface of the pedestal 2 and the size of the blank 3 mounted on the pedestal 2 can be increased. The effect is that the area of the recess 11 of the package 1 can be effectively utilized to realize a crystal unit and an oscillator with good characteristics.

Further, the second pedestal 6 is likewise formed in the same way, with the angled portions 62 of the four corners of the main body of the pedestal 6 being cut out obliquely off, so that the same effect can be achieved to make effective use of the area of the recess 11 of the package 1 to realize a crystal unit and oscillator of good characteristics.

Further, according to the second pedestal 6, the recess 6c is formed in the central portion of the surface on which the beveled blank 3 is mounted, and the edge portions 6a and 6b as the edges are formed at both ends of the recess 6c. Therefore, if a conductive adhesive is applied to the edges 6a and 6b and the blank 3 is mounted, the central portion of the blank 3, which has a large thickness, will be located above the recess 6c. Even if the central portion of the blank 3 protrudes downward, it will fit within the space of the recess 6c and prevent the central portion from being in contact with the surface of the pedestal 6. It has the effect of not interfering with the vibration of the blank 3 and improving the vibration characteristics. In addition, the use of the pedestal is effective in improving resistance to thermal stress and accelerations.

The disclosure is suitable for a pedestal, a crystal unit and an oscillator, wherein the area of the blank and electrodes can be sufficiently secured to improve the vibration characteristics without being in contact with the inner wall of the recess of the package where the angled portions of the recess are formed to be rounded.

According to the disclosure, the pedestal includes a recess provided at the center of the surface of the main body of the pedestal and edge portions adjacent to the recess, to which a beveled blank is fixed.

Further, according to the disclosure, in the crystal unit, the blank is fixed to the surface of any one of the above-mentioned pedestals, and the pedestal is provided on the substrate of the package.

Further, according to the disclosure, in the oscillator, the blank is fixed to the front surface of any one of the above-mentioned pedestals, the pedestal is provided on the substrate of the front surface of the package, and the oscillation circuit is provided on the substrate of the front surface or the back surface of the package.

According to the disclosure, it is a substantially rectangular pedestal on which a blank is mounted, and angled portions of four corners of main body of the pedestal are formed in a shape that is cut out obliquely. Even if the angled portions of the recess of the package are R-chamfered and formed to be rounded, it is possible to increase the dimensions of the long and short sides of the pedestal without being in contact with the inner wall of the recess. It is effective to obtain good vibration characteristics by sufficiently securing the area of the electrode and the blank.

Further, according to the disclosure, in the above-described pedestal, the pedestal is provided with a recess in the center of the surface of the body of the pedestal and an edge, adjacent to the recess, wherein the beveled blank is fixed. When the blank is mounted, the central portion of the blank, which is of a large thickness, is located above the recess in the pedestal body, preventing the blank from contacting the pedestal and having the effect of obtaining good vibration characteristics.

What is claimed is:

1. A pedestal for mounting a blank, wherein
pedestal is substantially rectangular, and
angled portions at four corners of a main body of the pedestal is formed in a shape that is cut out obliquely.

2. The pedestal according to claim 1, comprising;
a recess provided at a center of a surface of a main body of the pedestal; and
an edge portion adjacent to the recess to which the blank is fixed, wherein the blank is beveled.

3. A crystal unit, wherein
a blank is fixed to a surface of the pedestal according to claim 1, and
the pedestal is provided on a substrate of a package.

4. An oscillator, wherein
a blank is fixed to a surface of the pedestal according to claim 1,
the pedestal is provided on a substrate on a front surface of a package, and
an oscillator circuit is provided on the substrate on the front surface of the package, or a substrate on a back surface of the package.

5. A crystal unit, wherein
a blank is fixed to the surface of the pedestal according to claim 2, and
the pedestal is provided on a substrate of a package.

6. An oscillator, wherein
a blank is fixed to the surface of the pedestal according to claim 2,
the pedestal is provided on a substrate on a front surface of the package, and
an oscillator circuit is provided on the substrate on the front surface or a substrate on a back surface of the package.
